(19) United States
(12) Patent Application Publication
(10) Pub. No.: US 2010/0006913 A1
(43) Pub. Date: Jan. 14, 2010

(54) SEMICONDUCTOR DEVICE AND METHOD FOR MANUFACTURING THE SAME

(75) Inventors: Jun Lin, Kawasaki (JP); Hiroyuki Ogawa, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Tokyo (JP)

(21) Appl. No.: 12/499,197

(22) Filed: Jul. 8, 2009

(30) Foreign Application Priority Data
Jul. 11, 2008 (JP) 2008-181044

(51) Int. Cl. H01L 27/108; H01L 21/8234; H01L 21/8242

(52) U.S. Cl. 257/301; 438/240; 438/243; 257/E27.084; 257/E21.646; 257/E21.625

(57) ABSTRACT

A semiconductor device includes: a semiconductor substrate including a trench; a capacitor electrode formed in the trench; a first insulation film formed on a bottom of the trench and between the semiconductor substrate and the capacitor electrode; a second insulation film formed on a side wall of the trench and between the semiconductor substrate and the capacitor electrode; and a first metal oxide film formed at the bottom of the trench and between the capacitor electrode and the first insulation film.

### CROSS-REFERENCE TO RELATED APPLICATIONS

This application is based upon and claims the benefit of priority of the prior Japanese Patent Application No. 2008-181044, filed on Jul. 11, 2008, the entire contents of which are incorporated herein by reference.

### FIELD

The present invention relates to a semiconductor device and a method for manufacturing the semiconductor device. In particular, the present invention relates to a semiconductor device including a capacitor and a method for manufacturing the semiconductor device.

### BACKGROUND

Dynamic random access memories (DRAMs) having a single transistor/single capacitor configuration are used. There is a capacitor structure including a capacitor electrode and a semiconductor substrate facing the capacitor electrode where the capacitor electrode is used to apply a voltage to the semiconductor substrate to induce an inverted channel, thereby forming capacitance between the capacitor electrode and the channel.

To increase the capacitance of such a capacitor, a capacitor electrode may be provided in a region obtained by removing an insulation film in a device isolation region for isolating active regions. As a result, the side wall portion of the trench in the device isolation region may be advantageously used as a capacitor.

When the insulation film in the device isolation region is removed to a greater degree in the depth direction, a larger area of the side wall portion of the trench may be used as a capacitor. However, when the insulation film at the bottom of the trench becomes thin, leakage current tends to occur and sufficient device isolation is not provided.

### SUMMARY

According to aspects of an embodiment, a semiconductor device includes

a semiconductor substrate including a trench; a capacitor electrode formed in the trench; a first insulation film formed on a bottom of the trench and between the semiconductor substrate and the capacitor electrode; a second insulation film formed on a side wall of the trench and between the semiconductor substrate and the capacitor electrode; and a first metal oxide film formed at the bottom of the trench and between the capacitor electrode and the first insulation film.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a schematic plan view depicting an example of the configuration of a memory-logic semiconductor device;

FIG. 1B is a schematic plan view depicting an example of an arrangement of a memory cell group;

FIG. 2 is a schematic section view depicting a memory cell according to a first embodiment;

FIGS. 3A to 3L are schematic section views depicting processes for manufacturing a memory cell according to the first embodiment;

FIG. 4 is a schematic section view depicting a process for manufacturing a memory cell according to a second embodiment; and

FIGS. 5A to 5F are schematic section views depicting processes for manufacturing a memory cell according to a third embodiment.

### DESCRIPTION OF EMBODIMENTS

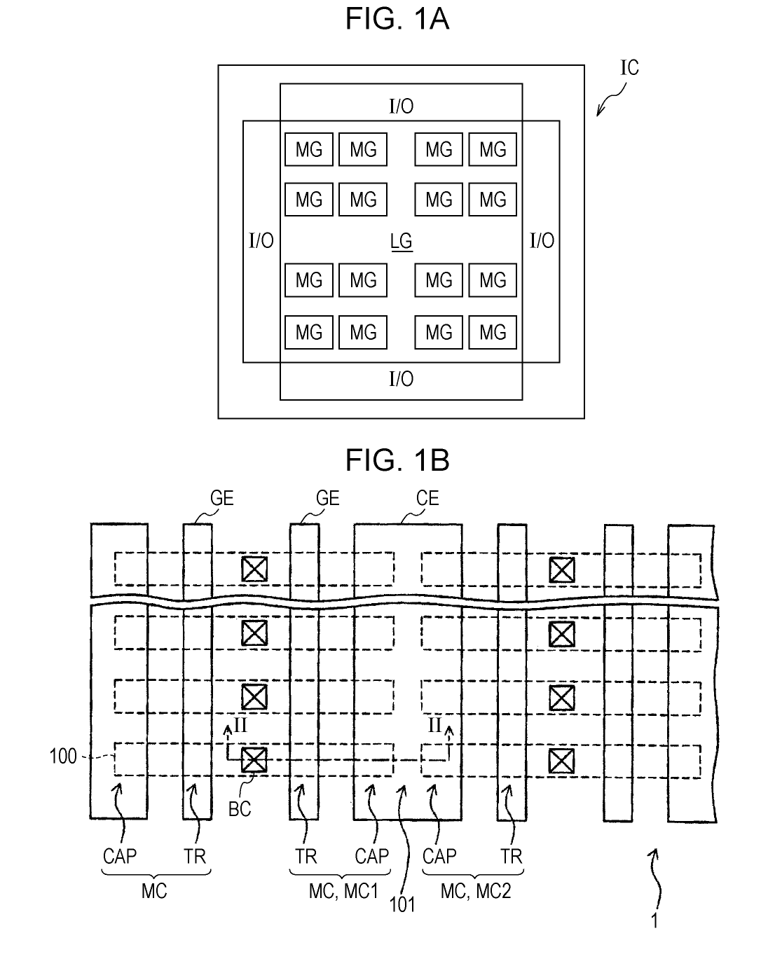

FIG. 1A schematically depicts an example of the configuration of a memory-logic semiconductor device IC in plan view. Input-output circuits I/O are provided in the periphery of the semiconductor device IC. A logical circuit LG including memory circuits MG provided at separate locations is provided in the center portion of the semiconductor device IC. Memory cell groups are provided in the memory circuits MG.

Referring to FIG. 1B, an example of a planar arrangement for a memory cell group will be described. A plurality of active regions 100 are arranged in rows and columns on a silicon substrate 1. The active regions 100 are elongated strips and arranged in a manner such that the longitudinal direction of the active regions 100 are in the direction of the rows. The active regions 100 are isolated from each other by device isolation regions 101.

Each active region 100 has a bit-line contact region BC in the center of the active region 100. A transistor TR and a capacitor CAP are formed on each side of the bit-line contact region BC. One memory cell MC includes one transistor TR and one capacitor CAP.

A gate electrode GE of the transistor TR is provided on each side of the bit-line contact region BC. A capacitor electrode CE is provided on a side of the gate electrode GE opposite the bit-line contact region BC so that the gate electrode GE is between the capacitor electrode CE and the bit-line contact region BC. Neighboring memory cells MC1 and MC2, which are formed in neighboring active regions 100 in the row direction, share a capacitor electrode CE.

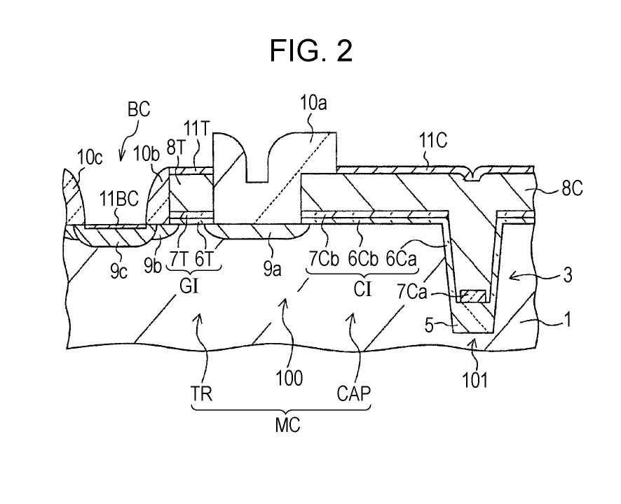

Referring now to FIG. 2, a memory cell according to a first embodiment will be described. FIG. 2 is a schematic section taken along the alternating long and short dashed line II-II in FIG. 1B and depicts a schematic sectional configuration of a region containing a single unit of the memory cell MC. The silicon substrate 1 is, for example, a substrate having a (001) plane (or an equivalent plane: (100) plane or (010) plane) as the main surface. The silicon substrate 1 may be, for example, an n-type substrate.

A metal oxide semiconductor (MOS) transistor TR includes p-type source/drain regions 9a and 9b (9c), a gate insulation film GI, and a gate electrode 8T. The gate insulation film GI includes a silicon oxide film 6T formed on the substrate 1 and a metal oxide film 7T formed on the silicon oxide film 6T. The metal oxide film 7T may be composed of, for example, hafnium silicon oxide. The gate electrode 8T may be composed of, for example, polysilicon.

The capacitor CAP includes a capacitor electrode 8C, the silicon substrate 1, and a capacitor insulation film CI between the capacitor electrode 8C and the silicon substrate 1. A voltage is applied to the capacitor electrode 8C so that a surface layer of the silicon substrate 1 facing the capacitor electrode 8C is inverted to induce a channel. As a result, a capacitance is formed between the capacitor electrode 8C and the channel in the surface layer of the silicon substrate 1.

The device isolation regions 101 for isolating the active regions 100 from each other may be formed by, for example, filling trenches formed in the silicon substrate 1 with a silicon oxide film. In the device isolation regions 101 for isolating neighboring active regions, a certain thickness of the silicon oxide film 5 in a trench 3 is left at the bottom of the trench 3 by filling the trench 3 with silicon oxide film 5 and then partially removing the silicon oxide film 5.

The capacitor electrode 8C is formed so as to enter the trench 3. The capacitor electrode 8C is formed so as to extend from the trench 3 to the upper surface of the silicon substrate 1. The capacitance of the capacitor CAP is the sum of the capacitance of the side wall portion of the trench 3 and the capacitance of the upper surface portion of the silicon substrate 1.

A silicon oxide film 6Ca is formed as the capacitor insulation film CI in the side wall portion of the trench 3. The silicon oxide film 6Ca in the side wall portion of the trench 3 is thinner than the silicon oxide film 5 at the bottom of the trench 3.

The capacitor insulation film CI on the upper surface of the silicon substrate 1 includes a silicon oxide film 6Cb formed on the substrate 1 and a metal oxide film 7Cb formed on the silicon oxide film 6Cb. The metal oxide film 7Cb may be composed of, for example, hafnium silicon oxide. The capacitor electrode 8C may be composed of, for example, polysilicon.

An end portion of the capacitor electrode 8C on the upper surface of the silicon substrate 1 is provided to overlap an end portion of the source/drain region 9a of the transistor TR on the capacitor CAP side. An end portion of the capacitor insulation film CI on the upper surface of the silicon substrate 1 between the capacitor electrode 8C and the silicon substrate 1 is also provided to overlap the end portion of the source/drain region 9a. In such a configuration, the source/drain region 9a of the transistor TR is connected to the channel of the capacitor CAP.

The bit-line contact region BC is provided on the source/drain region 9b (9c) on the side of the gate electrode 8T of the transistor TR opposite the source/drain region 9a.

The capacitance of the side wall portion on the left side of the bottom of the trench 3 and the capacitance of the upper surface of the silicon substrate 1 are used for the memory cell MC depicted in FIG. 2. The capacitance of the side wall portion on the right side of the bottom of the trench 3 is used for a neighboring memory cell MC on the right side of the memory cell MC depicted in FIG. 2. To achieve device isolation (reduction in leakage current), induction of a channel at the bottom of the trench 3 is preferably prevented on the surface layer of the silicon substrate 1.

The larger the thickness of the silicon oxide film 5 left at the bottom of the trench 3 is, the further leakage current may be reduced. However, the thicker the silicon oxide film 5 is, the smaller the area of the side wall portion of the trench 3 becomes, the side wall portion serving as capacitance. For this reason, to provide sufficient capacitance, the silicon oxide film 5 at the bottom of the trench 3 preferably has small thickness. Thus, a technique with which leakage current may be suppressed even when the silicon oxide film 5 at the bottom of the trench 3 has a small thickness is desired.

The capacitance may be increased not only by increasing the area of the side wall portion of the trench 3 but also by reducing the thickness of the capacitor insulation film 6Ca in the side wall portion of the trench 3.

In the capacitor CAP according to the first embodiment, a metal oxide film 7Ca containing a material providing a Fermi level pinning effect is formed on the silicon oxide film 5 at the bottom of the trench 3. The metal oxide film 7Ca may be composed of, for example, hafnium silicon oxide.

The Fermi level pinning effect occurs at the interface between the capacitor electrode 8C and the metal oxide film 7Ca. In this case, even when a voltage is applied to the capacitor electrode 8C, the Fermi level of the interface between the capacitor electrode 8C and the metal oxide film 7Ca tends not to shift. Thus, the surface of the semiconductor substrate 1 tends not to be subjected to voltage via the metal oxide film 7Ca and the silicon oxide film 5. As a result, a threshold voltage of inducing a channel in the surface layer of the silicon substrate 1 by the capacitor electrode 8C increases at the bottom of the trench 3. Thus, the generation of leakage current may be reduced. The material for the capacitor electrode 8C is not restricted to polysilicon and a metal may be used.

For example, 0.05 to 0.8 V of the voltage that the capacitor electrode 8C applies to the silicon oxide film 5 may be retained at the interface between the capacitor electrode 8C and the metal oxide film 7Ca. For example, a threshold voltage originally having a magnitude of 0.3 V may be increased to about a magnitude of 1.1 V. In this case, for example, when a voltage of 1 V is applied, generation of leakage current may be suppressed.

For example, an effect of increasing a threshold voltage by about 0.25 V may be provided for the metal oxide film 7Ca composed of HfₓSi_{y}O (x=0.09, y=0.91).

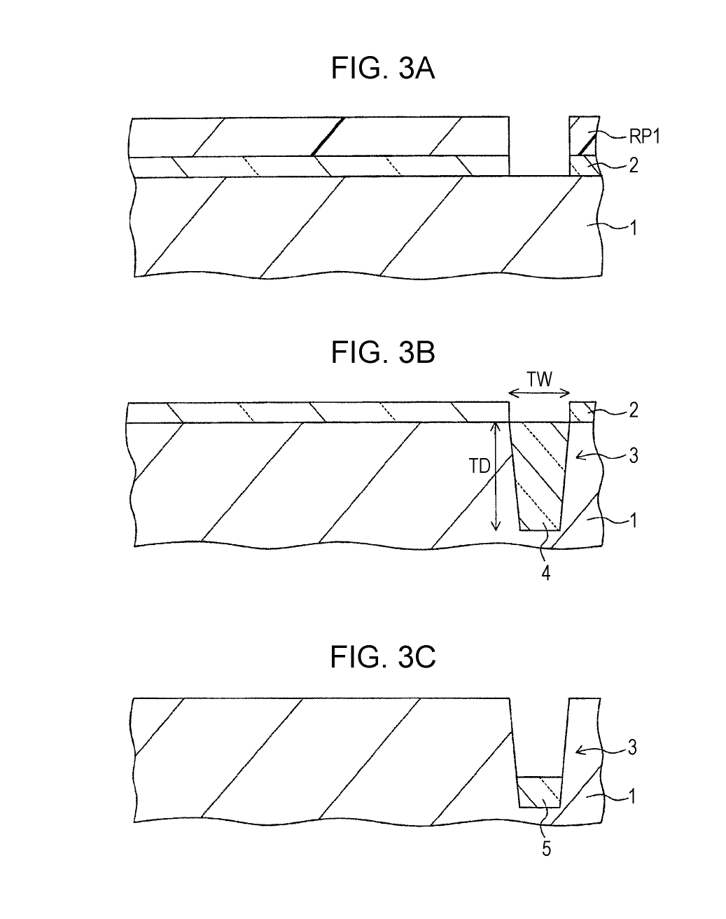

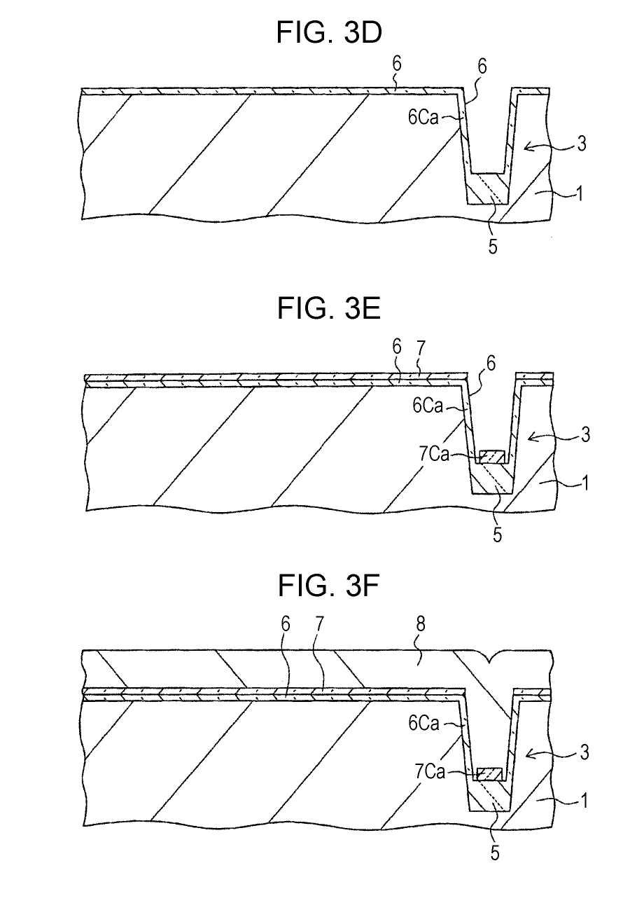

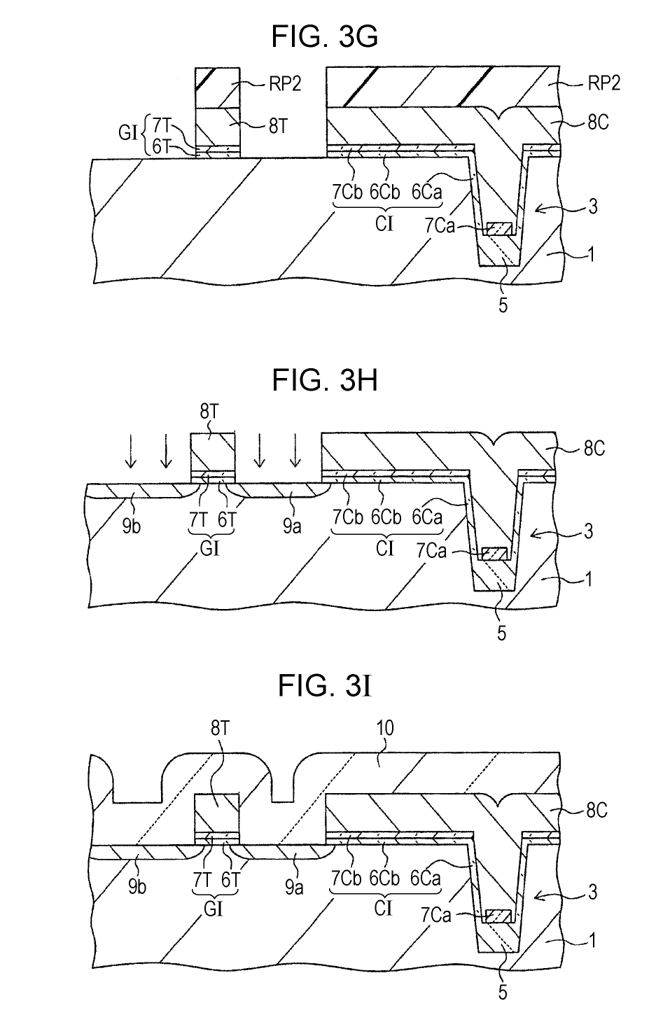

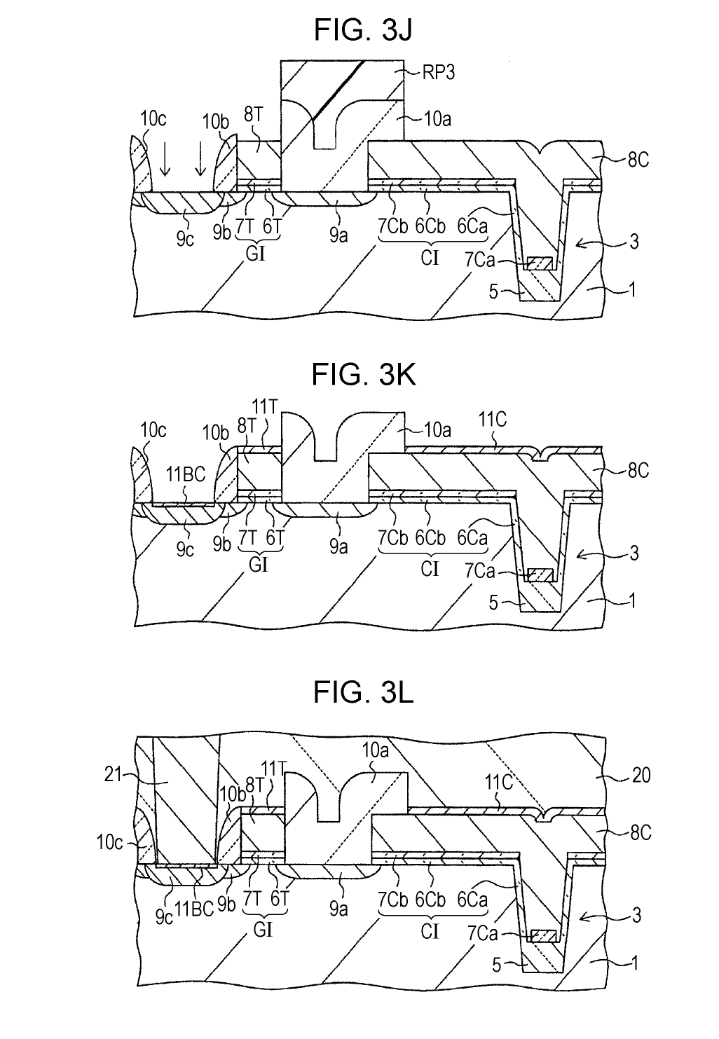

Hereinafter, processes for manufacturing the memory cell MC according to the first embodiment are described with reference to FIGS. 3A to 3L.

Referring first to FIG. 3A, a silicon nitride (Si₃N₄) film 2 is formed on the silicon substrate 1. The silicon substrate 1 may be, for example, an n-type (001) plane substrate. The silicon nitride film 2 is formed, for example, to have a thickness of 50 nm by chemical-vapor deposition (CVD) with a silane-based gas and ammonia serving as source gases.

A resist pattern RP1 having openings corresponding to the shape of the device isolation regions is then formed on the silicon nitride film 2. The silicon nitride film 2 may be patterned by, for example, dry etching with tetrafluorocarbon (CF₄) serving as an etching gas with the resist pattern RP1 serving as a mask. After that, the resist pattern RP1 is removed.

Referring next to FIG. 3B, the silicon substrate 1 is etched, for example, by dry etching with hydrogen bromide (HBr) and chlorine (Cl₂) serving as etching gases with the silicon nitride film 2 serving as a mask. Thus, the trench 3 is formed. For example, the trench 3 may have a depth TD of 320 nm and a width TW of 110 nm.

A silicon oxide film 4 is then deposited by, for example, high-density plasma (HDP) CVD with a silane-based gas and oxygen or CVD with tetraethoxysilane (TEOS) and oxygen to fill the trench 3 with the silicon oxide film 4.

Referring next to FIG. 3C, the silicon oxide film 4 is etched with, for example, hexafluorobutadiene (C₄F₆) serving as an etching gas such that the silicon oxide film 5 having a thickness sufficient for device isolation is left at the bottom of the trench 3. For example, the silicon oxide film 5 may have a thickness of 70 to 100 nm. After this etching, the silicon nitride film 2 is removed by, for example, being boiled with phosphoric acid or a mixed solution of phosphoric acid and hydrofluoric acid.

Referring now to FIG. 3D, a silicon oxide film 6 is formed by thermally oxidizing the exposed side wall of the trench 3 and the exposed upper surface of the silicon substrate 1. In the first embodiment, a silicon oxide film 6Ca formed on the side wall of the trench 3 is used as a capacitor insulation film in the side wall portion of the trench 3.

The silicon oxide film 6 grown by thermal oxidation (thermally oxidized silicon film 6) may have a thickness of, for example, 2 to 5 nm (e.g., 4 nm) on the upper surface of the silicon substrate 1. The side wall of the trench 3 may have, for example, a plane orientation of (110) (or equivalent plane). With such a plane orientation, the thermally oxidized silicon film 6 grown on the side wall of the trench 3 has a larger thickness than the thickness of the silicon oxide film 6 grown on the upper surface of the silicon substrate 1. For example, the silicon oxide film 6 formed on the upper surface of the silicon substrate 1 may have a thickness of 2 to 5 nm, whereas the silicon oxide film 6 formed on the side wall of the trench 3 may have a thickness of about 3 to 6 nm.

As described above, to increase the capacity of the capacitor, the silicon oxide film 6Ca on the side wall of the trench 3 preferably has small thickness. The thermally oxidized silicon film 6 is grown such that the silicon oxide film 6Ca on the side wall of the trench 3 has a suitable thickness (for example, about 3 to 6 nm) for a capacitor insulation film. The silicon oxide film 6 grown is too thin to use as a gate insulation film for an access transistor.

Referring then to FIG. 3E, the metal oxide film 7 is deposited on the silicon substrate 1. For example, HfₓSi_{y}O (for example, x=0.09, y=0.91) may be deposited by sputtering to a thickness of 1 nm.

By forming the metal oxide film 7 on the silicon oxide film 6 on the upper surface of the silicon substrate 1, an insulation film having an equivalent silicon oxide thickness (EOT: equivalent oxide thickness) suitable to use as a gate insulation film may be obtained. In the first embodiment, this laminate structure is used as a gate insulation film.

The metal oxide film 7Ca on the bottom of the trench 3 may also be formed at this time. As described above, the metal oxide film 7Ca increases the threshold voltage at the bottom of the trench 3, thereby suppressing leakage current.

In particular, when the metal oxide film 7 is deposited by a physical vapor deposition (PVD) method such as sputtering, deposition of the metal oxide film 7 on the side wall of the trench 3 is suppressed due to poor step coverage. The metal oxide film 7 is mainly deposited on the upper surface of the silicon substrate 1 and on the silicon oxide film 5 at the bottom of the trench 3. Thus, formation of a capacitor insulation film having a large thickness on the side wall of the trench 3 is suppressed.

To suppress deposition of the metal oxide film 7 on the side wall of the trench 3, the trench 3 preferably has a high aspect ratio to some extent. For example, the trench 3 preferably has an aspect ratio of about 2 to about 5. A method for depositing the metal oxide film 7 is not restricted to PVD, and another method such as CVD may also be used as long as deposition of the metal oxide film 7 on the side wall of the trench 3 is small.

Referring then to FIG. 3F, a polysilicon film 8 is formed on the silicon substrate 1 so as to fill the trench 3. The polysilicon film 8 may be formed by, for example, thermal CVD with a silane-based gas and hydrogen to have a thickness of, for example, 110 nm.

Referring then to FIG. 3G, a resist pattern RP2 having openings corresponding to the shape of the gate electrode and the capacitor electrode is formed and the polysilicon film 8 is etched with the resist pattern RP2 serving as a mask. As a result, the gate electrode 8T and the capacitor electrode 8C under the mask are left without being etched.

In this etching, the metal oxide film 7 and the silicon oxide film 6 are also patterned into the shape corresponding to the shape of the gate electrode 8T and the capacitor electrode 8C. Thus, a gate insulation film GI including a laminate structure of the silicon oxide film 6T and the metal oxide film 7T and the capacitor insulation film CI including a laminate structure of the silicon oxide film 6Cb and the metal oxide film 7Cb on the upper surface of the silicon substrate 1 are formed. After that, the resist pattern RP2 is removed.

Referring then to FIG. 3H, the extension regions 9a and 9b serving as the source/drain regions of the transistor are formed by implanting ions of a p-type impurity such as B with the gate electrode 8T and the capacitor electrode 8C serving as a mask.

Referring then to FIG. 3I, a silicon oxide film 10 is formed to a thickness of, for example, 80 nm to cover the gate electrode 8T and the capacitor electrode 8C.

Referring then to FIG. 3J, the silicon oxide film 10 is anisotropically etched by reactive ion etching or the like such that a side wall spacer 10b is left on the side wall of the gate electrode 8T. A side wall spacer 10c is also depicted on the side wall of the gate electrode of a transistor formed on the other side of the bit-line contact region.

A resist pattern RP3 is formed on the silicon oxide film 10 in a region between the gate electrode 8T and the capacitor electrode 8C. After the anisotropic etching, a silicon oxide film 10a covering the surface of the silicon substrate 1 in this region is left. After that, the resist pattern RP3 is removed.

A high concentration region 9c in which the bit-line contact region is to be provided is formed by implanting ions of a p-type impurity such as B with the side wall spacers 10b and 10c, the gate electrode 8T, the silicon oxide film 10a, and the capacitor electrode 8C serving as masks.

Referring then to FIG. 3K, silicide films 11BC, 11T, and 11C are formed on the high concentration region 9c, the gate electrode 8T, and the capacitor electrode 8C respectively by, for example, forming a Ni film by sputtering or the like, subjecting the Ni film to a heat treatment to cause silicide formation reaction, washing out unreacted portions of the Ni film, and, if necessary, subjecting the Ni film again to a heat treatment.

In this way, a memory cell may be formed. When a memory cell is integrated with a CMOS logic circuit, a PMOS transistor of the logic circuit and an access transistor of the memory cell may be formed in the same process.

An NMOS transistor may also be used as an access transistor of a memory cell. In this case, the access transistor of a memory cell and an NMOS transistor of a logic circuit may be formed in the same process.

Referring to FIG. 3L, a lower interlayer insulation film 20 is formed so as to cover a memory cell (and a MOS transistor of a logic circuit). The lower interlayer insulation film 20 is etched so as to form a contact hole, and the contact hole is filled with a conductive plug 21.

Multilayer interconnection is then formed by, for example, the processes disclosed in Description of Embodiments of Japanese Unexamined Patent Application Publication No. 2004-172590 (U.S. Pat. No. 6,949,830).

In summary, in the memory cell of the first embodiment, a metal oxide film is provided between the capacitor electrode and the device isolation insulation film at the bottom of the trench to increase threshold voltage of inducing a channel in the vicinity of the bottom of the trench. As a result, leakage current may be suppressed.

The capacitor insulation film in the side wall portion of the trench and the gate insulation film of the access transistor share a thermally oxidized silicon film. This thermally oxidized silicon film may be formed so as to have a thickness suitable to use as a capacitor insulation film in the side wall portion of the trench.

However, this thermally oxidized silicon film is too thin to use as a gate insulation film. To provide a gate insulation film having a suitable thickness, a metal oxide film is formed on the thermally oxidized silicon film. The metal oxide film used as a gate insulation film of the access transistor may be simultaneously formed in the formation of the metal oxide film at the bottom of the trench of the capacitor.

When such a metal oxide film is deposited by, for example, PVD, deposition of the metal oxide film on the side wall of the trench is suppressed. As a result, formation of the capacitor insulation film having a large thickness on the side wall portion of the trench is suppressed.

In this way, a good capacitor and a good access transistor of a memory cell are formed by the method described above. Such a method is useful for fabrication of memory cells of 65 nm generation or later.

Next, a memory cell according to a second embodiment will be described. This second memory cell is fabricated in approximately the same manner as the memory cell of the first embodiment up to and including the process depicted in FIG. 3E. The second memory cell is fabricated in approximately the same manner as in the first embodiment up to and including the process of depositing the metal oxide films 7Ca and 7 on the silicon oxide film 5 at the bottom of the trench 3 and on the upper surface of the silicon substrate 1. However, the silicon oxide film 5 left at the bottom of the trench 3 in the second embodiment has a smaller thickness than that in the first embodiment, and the thickness in the second embodiment may be, for example, 30 to 70 nm.

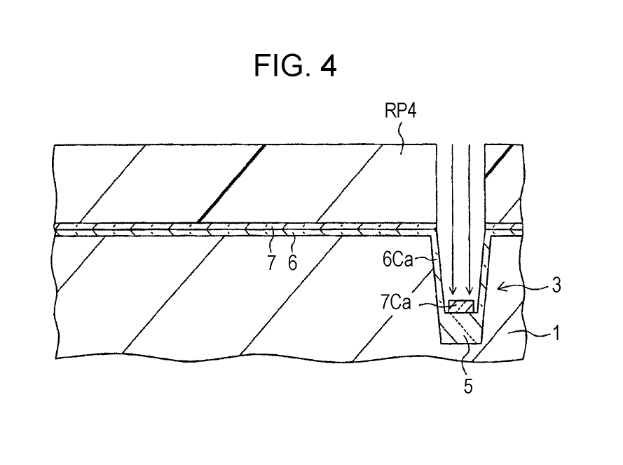

Referring then to FIG. 4, a resist pattern RP4 having an opening over the trench 3 is formed and, for example, Hf ions are implanted into the metal oxide film 7Ca at the bottom of the trench 3 at an acceleration energy of about 5 keV and at a dose of about 1×10¹⁶ atoms/cm². After that, the resist pattern RP4 is removed. The memory cell may be subsequently fabricated in approximately the same manner as depicted in FIG. 3F and in the first embodiment.

In the second embodiment, the Fermi level pinning effect is enhanced by increasing the composition ratio of the metal in the metal oxide film 7Ca at the bottom of the trench 3. In this case, leakage current tends to be suppressed even when the thickness of the silicon oxide film 5 at the bottom of the trench 3 is reduced. Thus, the area of the side wall portion of the trench serving as capacitance is easily increased.

The metal oxide film 7 on the upper surface of the silicon substrate 1 and the metal oxide film 7Ca at the bottom of the trench 3 may be formed to have different compositions. A metal oxide film suitable as a gate insulation film and a metal oxide film suitable for suppressing leakage current in a capacitor may be individually formed by selecting their compositions.

Next, a memory cell according to a third embodiment will be described. This third memory cell is fabricated in approximately the same manner as the memory cell of the first embodiment up to and including the process depicted in FIG. 3C. The third memory cell is fabricated in approximately the same manner as in the first embodiment up to and including leaving the silicon oxide film 5 having a thickness sufficient for device isolation at the bottom of the trench 3. However, as in the second embodiment, the silicon oxide film 5 left at the bottom of the trench 3 in the third embodiment has a thickness of, for example, 30 to 70 nm.

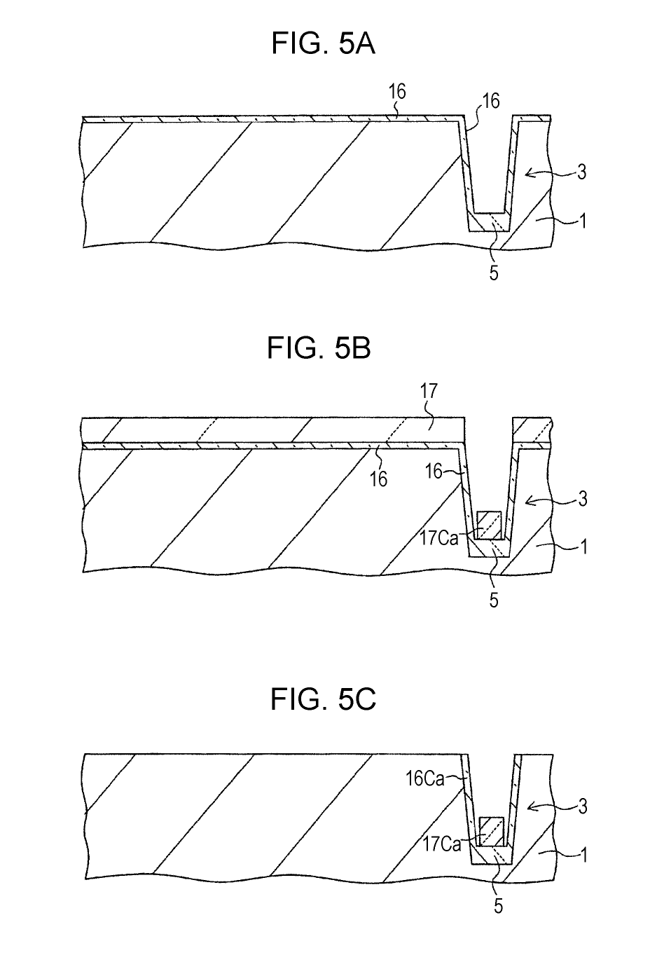

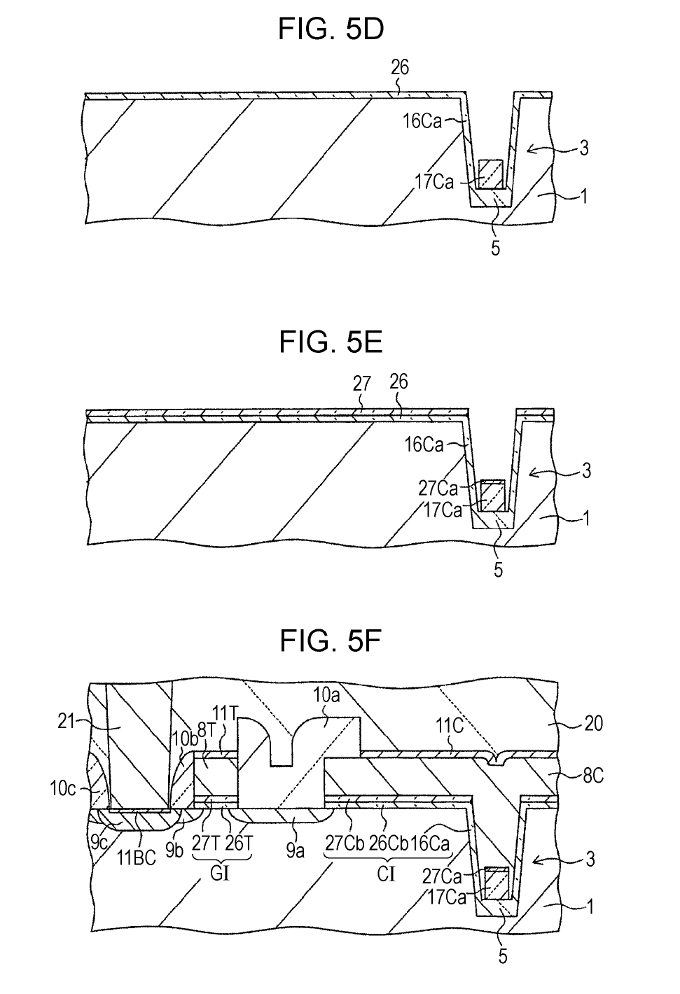

Referring then to FIG. 5A, the exposed side wall portion of the trench 3 and the exposed upper surface of the silicon substrate 1 are thermally oxidized to form a silicon oxide film 16 (a first thermal oxidation). The thickness of the thermally oxidized silicon film 16 may be, for example, 0.5 to 1 nm on the upper surface of the silicon substrate 1 and about 0.6 to 1.2 nm on the side wall of the trench 3 having the (110) plane.

Referring then to FIG. 5B, a metal oxide film 17 is deposited on the silicon substrate 1. For example, HfO₂ may be deposited by sputtering to a thickness of 5 to 20 nm. As a result, a metal oxide film 17Ca is formed on the silicon oxide film 5 at the bottom of the trench 3.

Referring then to FIG. 5C, the metal oxide film 17 and the silicon oxide film 16 on the upper surface of the silicon substrate 1 are removed by a wet treatment or by chemical mechanical polishing (CMP). For example, when the silicon oxide film 16 on the upper surface of the silicon substrate 1 is dissolved by being subjected to 5% HF for about 5 seconds, the metal oxide film 17 on the silicon oxide film 16 may also be removed. As a result, a silicon oxide film 16Ca on the side wall portion of the trench 3 and the metal oxide film 17Ca on the bottom of the trench 3 are left.

Referring then to FIG. 5D, a silicon oxide film 26 is grown on the upper surface of the silicon substrate 1 by thermally oxidizing the silicon substrate 1 (a second thermal oxidation). The silicon oxide film 16Ca on the side wall portion of the trench 3 is also grown. The silicon oxide film 16Ca may be grown, for example, to a thickness of 3 to 6 nm. The silicon oxide film 26 on the upper surface of the silicon substrate 1 may be grown, for example, to a thickness of about 2 to 5 nm.

Referring then to FIG. 5E, a metal oxide film 27 is deposited on the silicon substrate 1. For example, HfₓSi_{y}O (for example, x=0.09, y=0.91) may be deposited by sputtering to a thickness of 1 nm. As a result, a metal oxide film 27Ca is deposited on the metal oxide film 17Ca at the bottom of the trench 3. The memory cell may be subsequently fabricated in approximately the same manner as depicted in FIG. 3F and in the first embodiment.

Referring to FIG. 5F, the laminate structure of the silicon oxide film 26 and the metal oxide film 27 are patterned to form a gate insulation film GI (a silicon oxide film 26T and a metal oxide film 27T) and a capacitor insulation film CI (a silicon oxide film 26Cb and a metal oxide film 27Cb) on the upper surface of the silicon substrate 1. The laminate structure of the metal oxide film 17Ca and the metal oxide film 27Ca are used as a metal oxide film at the bottom of the trench 3.

In the third embodiment, the silicon oxide film 16Ca grown by the second thermal oxidation on the side wall portion of the trench 3 may be made to have a thickness that is small enough to be suitable to use as a capacitor insulation film. In this case, even when the silicon oxide film 26 on the upper surface of the silicon substrate 1 is too thin to use as a gate insulation film, deposition of the metal oxide film 27 on the silicon oxide film 26 may provide the gate insulation film GI having a suitable thickness.

A metal oxide film suitable for a gate insulation film and a metal oxide film suitable for suppressing leakage current at the bottom of a trench may be individually formed.

The metal oxide films 17Ca and 27Ca at the bottom of the trench 3 are formed so as to be thicker than the metal oxide film 27 used for the gate insulation film GI and the capacitor insulation film CI on the upper surface of the silicon substrate 1. By forming thick metal oxide films at the bottom of the trench 3, higher Fermi level pinning effect may be provided. As a result, even when the thickness of the silicon oxide film 5 at the bottom of the trench 3 is reduced, leakage current may be easily suppressed. Thus, the side wall portion of the trench serving as capacitance may be easily widened.

In the first to the third embodiments above, examples in which hafnium silicon oxide films and hafnium oxide films are formed at the bottoms of trenches have been described. Alternatively, other materials providing the Fermi level pinning effect may also be used for forming films at the bottoms of trenches. Metal oxides are expected to provide the Fermi level pinning effect to some extent. In general, a material having a higher relative dielectric constant provides a higher Fermi level pinning effect. In particular, materials having a relative dielectric constant of 7 or more are presumably useful.

Examples of such a material for forming a metal oxide film at the bottom of a trench include hafnium silicon oxide and hafnium oxide (HfₓSi_{y}O (for example, x=0.05 to 1.00, x+y=1) or HfO₂) and tantalum oxide. In addition to these oxides, the examples further include TaₓSi_{y}O, ZrₓSi_{y}O, TiₓSi_{y}O, PbₓZr_{y}Ti_{z}O, SrₓTi_{y}O, and AlₓSi_{y}O.

An expected increase in threshold voltage at the bottom of a trench is, for example, about 0.05 to about 0.8 V. The preferred thickness of a metal oxide film formed at the bottom of a trench is, for example, in the range of 1 to 30 nm.

A preferred metal oxide used for forming a gate insulation film (and a capacitor insulation film on the upper surface of a substrate) is, for example, hafnium silicon oxide (HfₓSi_{y}O (for example, x=0.05 to 0.35, x+y=1)). A preferred thickness of this gate insulation film is, for example, in the range of 0.3 to 1.5 nm.

A preferred thickness of a device isolation insulation film (silicon oxide film 5 in the embodiments) left on the bottom of a trench is, for example, in the range of 20 to 100 nm.

In the first to the third embodiments above, (001) plane silicon substrates are used. Alternatively, other semiconductor substrates may also be used in accordance with the characteristics or the like of desired transistors. For example, a silicon substrate having the (110) plane (or equivalent plane: (101) plane or (011) plane) as the main surface may also be used.

By providing a metal oxide film between an electrode formed in a trench and an insulation film formed on the bottom of the trench, voltage at which an inverted channel is induced in the bottom portion of the trench of a semiconductor substrate may be increased. As a result, leakage current may be suppressed.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A semiconductor device comprising:
a semiconductor substrate including a trench;
a capacitor electrode formed in the trench;
a first insulation film formed on a bottom of the trench and between the semiconductor substrate and the capacitor electrode;
a second insulation film formed on a side wall of the trench and between the semiconductor substrate and the capacitor electrode; and
a first metal oxide film formed at the bottom of the trench and between the capacitor electrode and the first insulation film.

2. The semiconductor device according to claim 1, further comprising:
a transistor including a source/drain region formed in the semiconductor substrate, a gate electrode, and a gate insulation film; and
an insulation film provided between an upper surface of the semiconductor substrate and the capacitor electrode,
wherein the capacitor electrode is formed to extend to the upper surface of the semiconductor substrate and to overlap an end of the source/drain region of the transistor.

3. The semiconductor device according to claim 2, wherein the gate insulation film of the transistor includes a second metal oxide film, and the second metal oxide film has substantially the same composition as the composition of the first metal oxide film.

4. The semiconductor device according to claim 2, wherein the gate insulation film of the transistor includes a second metal oxide film, and the first metal oxide film has a higher composition ratio of metal than a composition ratio of metal of the second metal oxide film.

5. The semiconductor device according to claim 2, wherein the gate insulation film of the transistor includes a second metal oxide film, and the first metal oxide film is thicker than the second metal oxide film.

6. The semiconductor device according to claim 2, wherein the gate insulation film of the transistor includes a second metal oxide film, and the insulation film provided between the upper surface of the semiconductor substrate and the capacitor electrode includes a metal oxide film having a thickness substantially equal to a thickness of the second metal oxide film.

7. The semiconductor device according to claim 3, wherein the second metal oxide film has a thickness in the range of 0.3 nm to 1.5 nm.

8. The semiconductor device according to claim 1, wherein the first metal oxide film has a thickness in the range of 1 nm to 30 nm.

9. The semiconductor device according to claim 1, wherein the first metal oxide film at least contains any one of hafnium silicon oxide, hafnium oxide, tantalum oxide, TaₓSi_{y}O, ZrₓSi_{y}O, TiₓSi_{y}O, PbₓZr_{y}Ti_{z}O, SrₓTi_{y}O, and AlₓSi_{y}O.

10. The semiconductor device according to claim 1, wherein the first insulation film formed on the bottom of the trench is thicker than the second insulation film formed on the side wall of the trench.

11. The semiconductor device according to claim 1, wherein the first insulation film formed on the bottom of the trench has a thickness in the range of 20 nm to 100 nm.

12. The semiconductor device according to claim 1, wherein the second insulation film formed on the side wall of the trench has a thickness in the range of 3 nm to 6 nm.

13. The semiconductor device according to claim 1, wherein the first insulation film is a silicon oxide film.

14. The semiconductor device according to claim 1, wherein the second insulation film is a silicon oxide film.

15. The semiconductor device according to claim 1, wherein the semiconductor substrate is a silicon substrate.

16. A method for producing a semiconductor device, comprising:
forming a trench in a semiconductor substrate;
forming an insulation film on a bottom of the trench;
forming an insulation film on a side wall of the trench;
forming a metal oxide film on the insulation film formed on the bottom of the trench; and
forming an electrode in the trench.

17. The method according to claim 16, wherein
when forming the insulation film on the side wall of the trench, the insulation film is formed on the side wall of the trench as well as on an upper surface of the semiconductor substrate;
when forming the metal oxide film, the metal oxide film is formed on the insulation film on the bottom of the trench as well as on the insulation film on the upper surface of the semiconductor substrate; and
when forming the electrode, the electrode is formed in the trench as well as on the metal oxide film on the upper surface of the semiconductor substrate,
the method further comprising:
forming a capacitor electrode including a part of the capacitor electrode formed in the trench and a gate electrode separated from the capacitor electrode; and
forming a transistor including a source/drain region, the gate electrode, and a gate insulation film provided between the gate electrode and the semiconductor substrate and including a laminate of the insulation film and the metal oxide film, by forming the source/drain region by implanting an impurity into a first region and a second region in the semiconductor substrate, the first region being provided between the capacitor electrode and the gate electrode, and the second region being provided opposite the first region with the gate electrode therebetween.

18. The method according to claim 17, further comprising:
after forming the metal oxide film, forming a mask above the semiconductor substrate, the mask having an opening over the trench, and implanting a metal element into the metal oxide film formed on the bottom of the trench.

19. The method according to claim 16, wherein
the forming of the insulation film on the side wall of the trench includes forming a first insulation film on the side wall of the trench, and forming a second insulation film on the first insulation film;
the forming of the metal oxide film includes forming a first metal oxide film on the insulation film formed on the bottom of the trench, and forming a second metal oxide film on the first metal oxide film;
when forming the first insulation film, the first insulation film is formed on the side wall of the trench as well as on an upper surface of the semiconductor substrate;
when forming the first metal oxide film, the first metal oxide film is formed on the insulation film on the bottom of the trench as well as on the first insulation film on the upper surface of the semiconductor substrate; and
the method further comprises:
removing the first metal oxide film and the first insulation film on the upper surface of the semiconductor substrate;
when forming the second insulation film, forming the second insulation film on the first insulation film on the side wall of the trench as well as on the upper surface of the semiconductor substrate;
when forming the second metal oxide film, forming the second metal oxide film on the first metal oxide film on the bottom of the trench as well as on the second insulation film on the upper surface of the semiconductor substrate;
when forming the electrode, forming the electrode in the trench as well as on the second metal oxide film on the upper surface of the semiconductor substrate;
forming a capacitor electrode including the part formed in the trench and a gate electrode separated from the capacitor electrode; and
forming a transistor including a source/drain region, the gate electrode, and a gate insulation film provided between the gate electrode and the semiconductor substrate and including a laminate of the second insulation film and the second metal oxide film, by forming the source/drain region by implanting an impurity into a first region and a second region in the semiconductor substrate, the first region being provided between the capacitor electrode and the gate electrode and the second region being provided opposite the first region with the gate electrode therebetween.

20. The method according to claim 16, wherein, when forming the metal oxide film, the metal oxide film is deposited by physical vapor deposition.
